(19) United States
(12) Patent Application Publication
(10) Pub. No.: US 2006/0154490 A1
(43) Pub. Date: Jul. 13, 2006

(54) Liquid treating apparatus

(75) Inventors: Tetsuyuki Narabayashi, Shinagawa-ku (JP); Shinji Kunimoto, Shinagawa-ku (JP); Makoto Kasai, Shinagawa-ku (JP); Kenji Toda, Amagasaki-shi (JP)

Correspondence Address: THE WEBB LAW FIRM, P.C., 700 KOPPERS BUILDING, 436 SEVENTH AVENUE, PITTSBURGH, PA, 15219, US

(73) Assignees: Mitsui Mining & Smelting Co., Ltd., Shinagawa-ku (JP); MEC Company Ltd., Amagasaki-shi (JP)

(21) Appl. No.: 11/330,022

(22) Filed: Jan. 11, 2006

(30) Foreign Application Priority Data
Jan. 12, 2005 (JP) 2005-005178

(51) Int. Cl. H01L 21/302

(52) U.S. Cl. 438/745

(57) ABSTRACT

A liquid treating apparatus includes an etchant discharging nozzle for discharging a treating solution (E) onto an upper surface of a film carrier tape for mounting an electronic component (T) from above and a treating solution contact prevention chamber disposed on an upstream side of a liquid treating start position (A) in which an etchant (E) discharged onto an upper surface of the film carrier tape (T) through an etchant discharging nozzle starts etching and serving to prevent the discharged solution from coming in contact with the film carrier tape (T) before the liquid treating start position (A). The apparatus also includes a liquid sealing lip member of a first infiltration preventing member and an upper lip component and a lower lip component of a second infiltration preventing member disposed in the treating solution contact prevention chamber.

### FIELD OF THE INVENTION

The present invention relates to a liquid treating apparatus to be used in a liquid treating process for discharging a treating solution to a space under pressure in the manufacture of a film carrier tape for mounting electronic component (a TAB (Tape Automated Bonding) tape, a COF (Chip on Film) tape, a T-BGA (Tape Ball Grid Array) tape, a CSP (Chip Size Package) tape, an ASIC (Application Specific Integrated Circuit) tape, a 2-metal (double-sided wiring) tape, a multilayer wiring tape or the like (which will be hereinafter referred to as a “film carrier tape”).

### DESCRIPTION OF THE RELATED ART

With the development of electronics industry, there has been rapidly increased a demand for a printed wiring board for mounting an electronic component such as an IC (integrated circuit) chip or an LSI (large scale integrated circuit). However, there have been required a reduction in a size and weight and an enhancement in a function in electronic equipment. As a method of mounting these electronic components, recently, there has been employed a mounting method using film carrier tapes such as a TAB tape, a COF tape, a TBGA tape, an ASIC tape, a 2-metal (double-sided wiring) tape and a multilayer wiring tape.

Particularly, in the electronics industry for a flat panel display such as a liquid crystal display unit (LCD), for which an increase in a fineness, a reduction in a thickness and a reduction in a frame area of a liquid crystal screen have been demanded, for example, a personal computer, a cellular phone or a liquid crystal television, or a PDP (plasma display panel), an importance has been increased.

Conventionally, such a film carrier tape for mounting electronic component is manufactured through the following steps as a method of manufacturing a COF tape, for example.

More specifically, first of all, a copper layer is formed on an insulating film to be a base material such as a polyimide film by a sputtering and plating method to form a two-layer tape. Thereafter, a desirable opening such as a sprocket hole is formed by a pressing machine, and a photoresist is then applied to a whole upper surface of the copper layer.

Thereafter, the photoresist is exposed in a desirable pattern shape with ultraviolet rays by using a photomask, and the photoresist portion thus exposed is dissolved and removed with a developer. A copper layer portion which is not covered with the photoresist is chemically dissolved (an etching treatment) and removed with acid to be an etchant, and furthermore, the photoresist is dissolved and removed with an alkali solution so that a desirable wiring pattern is formed by the copper layer remaining on the insulating film.

In order to prevent a short circuit from being caused by dust, whisker or migration in mounting and to mutually protect and insulate wirings, subsequently, a solder resist to be an insulating resin is applied through a screen provided with an application pattern using a squeegee by a screen printing method onto portions in the wiring pattern excluding lead portions, for example, an inner lead to be connected to a device (an electronic component) such as an IC chip and an outer lead to be connected to a liquid crystal display unit or the like, and is then dried and cured to form a solder resist coating layer.

In order to prevent the oxidation and discoloration of an exposed lead portion and to maintain a bonding strength to a connecting portion such as a bump of a device to be connected to the lead portion, thereafter, the lead portion is subjected to tinning, gold plating, eutectic alloy plating of a Pb free solder such as Sn—Bi or the like, and the tape is thus manufactured.

In the manufacture of the film carrier tape for mounting electronic component, at the etching step, an etching treatment has conventionally been carried out by using an etching device shown in FIG. 4.

More specifically, as shown in FIG. 5, there is used a film carrier tape 100 having, on an upper surface of an insulating film 114, a copper layer portion 104 covered with a photoresist 102 and a copper layer portion 108 which is not covered with the photoresist 102 but is exposed from a surface. Then, the film carrier tape 100 is continuously supplied into an etching device 110 as shown in an arrow of FIG. 4.

In the etching device 110, a plurality of etchant discharging nozzles 112 is disposed apart from each other at a predetermined interval in the direction of the supply of a film above the film carrier tape 100. These etchant discharging nozzles 112 are provided in one line or more in the direction of the delivery of the film 100. An etchant E is discharged onto an upper surface of the film 100 from the etchant discharging nozzles 112.

As shown in FIG. 5, then, the copper layer portion 108, which is not covered with the photoresist 102, is removed by etching and a wiring pattern 116 is formed by the copper layer 104 remaining on the insulating film 114.

In such an etching process, it is ideal that the copper layer portion 108, which is not covered with the photoresist 102, is etched with the etchant E in a perpendicular direction from above and the wiring pattern 116 is thus formed at an accurate pitch as shown in FIG. 5.

However, in such an etching process, as shown in FIG. 6, in some cases, a side etching portion 118 is generated by a so-called “side etching” function, in which an upper part of the copper layer portion 104 covered with the photoresist 102 is etched in a lateral direction in addition to the copper layer portion 108 which is not covered with the photoresist 102. As a result, copper remaining portions 120 and 122 are generated in some cases.

When the copper remaining portions 120 and 122 are generated, a distance therebetween is reduced. For this reason, particularly, an accurate wiring pitch cannot be obtained in case of a small pitch. Consequently, a short circuit is caused between the copper remaining portions 120 and 122 or is caused by migration therebetween so that a defective product is manufactured in some cases.

Under the existing circumstances, particularly, a wiring pitch has recently been reduced to be 30 μm or less, for example. The influence of the short circuit is remarkable.

Therefore, Patent Document 1 (Japanese Laid-Open Patent Publication No. 2003-306784) has proposed such an etchant that the side etching can be prevented and the copper layer portion 108 which is not covered with the photoresist 102 is etched perpendicularly from above with the etchant E so that a wiring pattern can be formed at an accurate pitch as shown in FIG. 5.

More specifically, in the Patent Document 1, there has been proposed an etchant containing a side etching inhibiting additive which has a capability of etching copper in the early stage of an etching treatment and forms a slightly soluble compound (a metallic compound) 124 on an etched surface of a copper layer touching the etchant, thereby inhibiting the side etching with the passage of time as shown in FIG. 7.

Examples of the side etching inhibiting additive contained in the etchant include tamaline, N-oleyl sarcosinate K, acid phthalic anhydride, thiazoles, triazoles and the like in the Patent Document 1.

[Patent Document 1] Japanese Laid-Open Patent Publication No. 2003-306784

In the case in which the ordinary etchant E is used in the conventional etching device 110 shown in FIG. 4, a part of the etchant E jetted from the etchant discharging nozzle 112 is changed into a mist and thus floats in an etching chamber 101. For this reason, the mist-like liquefied etchant E discharged from the liquid discharging nozzle 112 to the upper surface of the film splashes on a portion 100a of the film carrier tape 100 which is placed on an upstream side of a liquid treating start position A in which the etchant E starts to etch a conductive layer in some cases. In these cases, there is a possibility that an etching reaction might progress to generate stains, a disconnection of a wiring pattern and the like.

However, in particular, in the case in which the film carrier tape 100 is subjected to the etching treatment by means of the conventional etching device 110 shown in FIG. 4 using the etchant containing the side etching inhibiting additive described in the Patent Document 1, a slightly soluble compound (a metallic compound) 126 is formed on the upper surface of the copper layer portion 108 which is not covered with the photoresist 102 as shown in FIG. 8 when a mist-like etchant E″ thus splashes.

For this reason, the slightly soluble compound 126 functions as a resist layer and a copper remaining portion 128 is generated thereunder. Also after the photoresist 102 is removed with alkali, consequently, the copper remaining portion 128 is left to generate a short circuit of a wiring pattern which is not caused in the case in which an ordinary etchant is used. Thus, a defective product is manufactured. Accordingly, it is necessary to strictly manage the mist-like etchant.

In consideration of such existing circumstances, it is an object of the present invention to provide a liquid treating apparatus, which can prevent a mist-like liquid etchant discharged from a liquid discharging nozzle to an upper surface of a substance to be surface treated such as a film from splashing over a portion of the surface treated substance placed on an upstream side of a liquid treating start position A, in which the etchant starts to etch a conductive layer, particularly, an upstream side of a second infiltration preventing member, and capable of carrying out a treatment with a treating solution more reliably and preventing a defective product from being generated also in a state in which the treating solution jetted from the liquid discharging nozzle is changed into the mist and thus floats in a treating chamber.

### SUMMARY OF THE INVENTION

The present invention has been made in order to solve the problems and to attain the object in the conventional art described above, and provides a liquid treating apparatus for carrying out a predetermined liquid treatment for a substance to be surface treated which is supplied continuously, comprising:

a treating solution discharging device for discharging a treating solution to a liquid treating surface of the surface treated substance; and

a treating solution contact prevention chamber, which is provided in an outer position in a direction of delivery of the surface treated substance from a liquid treating terminal position, in which the treating solution is discharged to the liquid treating surface of the surface treated substance by means of the treating solution discharging device, and

which serves to prevent the discharged solution from coming in contact with the surface treated substance in an outer position in the direction of the delivery of the surface treated substance from the liquid treating terminal position,

the treating solution contact prevention chamber comprising:
a first infiltration preventing member disposed on the liquid treating terminal position side of the treating solution contact prevention chamber and serving to prevent the treating solution, which is discharged from the treating solution discharging device and flowing along the liquid treating surface of the surface treated substance, from infiltrating into the treating solution contact prevention chamber; and
a second infiltration preventing member disposed on an inside of the treating solution contact prevention chamber from the first infiltration preventing member and serving to prevent the treating solution, which is discharged from the treating solution discharging device and then floating in a chamber, from infiltrating into the treating solution contact prevention chamber; and

wherein the liquid treating apparatus serves to carry out a predetermined liquid treatment in a liquid treating chamber to be a limited space for the surface treated substance.

Moreover, the present invention provides a liquid treating method for discharging a treating solution to a liquid treating surface of a substance to be surface treated by means of a treating solution discharging device for the surface treated substance which is supplied continuously, thereby carrying out a predetermined liquid treatment, comprising the steps of:

delivering the surface treated substance to pass through an inside of a treating solution contact prevention chamber, which is provided in an outer position in a direction of delivery of the surface treated substance from a liquid treating terminal position, in which a treating solution is discharged to the liquid treating surface of the surface treated substance by the treating solution discharging device; and

preventing the treating solution, which is discharged from the treating solution discharging device and flowing along the liquid treating surface of the surface treated substance, from infiltrating into the treating solution contact prevention chamber, by means of a first infiltration preventing member, which is disposed on the liquid treating terminal position side of the treating solution contact prevention chamber; and

preventing the treating solution, which is discharged from the treating solution discharging device and then floating in a chamber, from infiltrating into the treating solution contact prevention chamber, by means of a second infiltration preventing member disposed on an inside of the treating solution contact prevention chamber from the first infiltration preventing member; and

discharging the treating solution through the treating solution discharging device, thereby carrying out a predetermined liquid treatment for the surface treated substance, in the state that,

wherein the liquid treating apparatus serves to carry out a predetermined liquid treatment in a liquid treating chamber to be a limited space for the surface treated substance.

By such a structure, the surface treated substance passes through the inside of the treating solution contact prevention chamber, which is disposed in the outer position in the direction of the delivery of the surface treated substance from the liquid treating terminal position, for example, the inside of the treating solution contact prevention chamber, which is disposed on the upstream side of a liquid treating start position A to be the liquid treating terminal position. Therefore, it is possible to prevent the discharged solution from coming in contact with the surface treated substance before the liquid treating start position A.

Then, the treating solution is discharged onto the upper surface of the surface treated substance, which is passing through the treating solution contact prevention chamber, by means of the treating solution discharging device. Consequently, it is possible to carry out a predetermined liquid treatment over the surface treated substance, which is passing through the treating solution contact prevention chamber.

Accordingly, the solution, which is discharged by means of the treating solution discharging device and floating like a mist, can be prevented from coming in contact with the surface treated substance before the liquid treating start position A, in a state in which the discharged solution is almost isolated through the treating solution contact prevention chamber. Consequently, it is possible to reliably carry out a treatment with the treating solution. Thus, it is possible to prevent a defective product from being generated.

Moreover, the surface treated substance passes through the inside of the treating solution contact prevention chamber, which is disposed in the outer position in the direction of the delivery of the surface treated substance from the liquid treating terminal position, for example, the inside of the treating solution contact prevention chamber, which is disposed on the downstream side of a liquid treating end position B to be the liquid treating terminal position. Therefore, it is possible to prevent the discharged solution from coming in contact with the surface treated substance after the liquid treating end position B.

Consequently, it is possible to prevent the etchant floating like the mist from excessively treating the surface of the surface treated substance in contact therewith. Thus, it is possible to prevent a defective product from being generated.

Furthermore, the first infiltration preventing member can prevent the treating solution, which is discharged from the treating solution discharging device and flowing along the liquid treating surface of the surface treated substance, from infiltrating into the inside of the treating solution contact prevention chamber.

The second infiltration preventing member, which is disposed on the further inside of the treating solution contact prevention chamber, can prevent the treating solution, which is discharged from the treating solution discharging device and then floating like the mist, from infiltrating into the inside of the treating solution contact prevention chamber in place of the first infiltration preventing member.

More specifically, a cutoff is carried out doubly in a sense in such a manner that the first infiltration preventing member can prevent the treating solution flowing along the treated surface of the surface treated substance from infiltrating into the treating solution contact prevention chamber and the second infiltration preventing member can prevent the treating solution floating like the mist from infiltrating into the treating solution contact prevention chamber.

Accordingly, it is possible to reliably prevent the discharged solution from coming in contact with the surface treated substance and to surely carry out a treatment with the treating solution. Thus, it is possible to prevent a defective product from being generated.

Moreover, the present invention is characterized in that the first infiltration preventing member includes a liquid sealing lip member.

Thus, the first infiltration preventing member includes a lip-shaped liquid sealing lip member. Consequently, the treating solution, which is discharged from the treating solution discharging device and then floating like the mist in the chamber, can be prevented from infiltrating into the treating solution contact prevention chamber through the shield of the body portion of the liquid sealing lip member.

In this case, furthermore, the treating solution, which is discharged from the treating solution discharging device and flowing along the liquid treating surface of the surface treated substance, comes in contact with the tip portion of the liquid sealing lip member between the tip portion of the liquid sealing lip member and the liquid treating surface of the surface treated substance. As a result, a surface tension is applied and a liquid collection is thus generated. A so-called water sealing state is brought by the liquid collection so that the infiltration can be prevented by the water sealing effect.

In addition, thus, the portion between the tip portion of the liquid sealing lip member and the liquid treating surface of the surface treated substance is sealed with the liquid collection of the treating solution. Therefore, it is also possible to prevent the treating solution, which is floating like the mist, from infiltration from a portion between the tip portion of the liquid sealing lip member and the liquid treating surface of the surface treated substance into the treating solution contact prevention chamber.

Moreover, the present invention is characterized in that the liquid sealing lip member is disposed to be inclined to the liquid treating surface side of the surface treated substance toward the liquid treating terminal position side and is constituted to prevent the treating solution from infiltrating into the treating solution contact prevention chamber through the liquid treating surface of the surface treated substance.

By such a structure, the liquid sealing lip member and the liquid treating surface of the surface treated substance are mutually disposed at some angle. Therefore, the liquid collection described above is easily generated between the tip portion of the liquid sealing lip member and the liquid treating surface of the surface treated substance. Consequently, it is possible to enhance the infiltration blocking effect of the treating solution by the water sealing effect.

Furthermore, the present invention is characterized in that an inclination angle α between the liquid sealing lip member and the liquid treating surface of the surface treated substance is 5 to 135 degrees.

If the inclination angle α is formed between the liquid sealing lip member and the liquid treating surface of the surface treated substance within this range, the liquid collection described above is generated reliably. Therefore, it is possible to generate the liquid collection and to hinder the treating solution from infiltrating into the treating solution contact prevention chamber from the portion between the tip portion of the liquid sealing lip member and the liquid treating surface of the surface treated substance.

Moreover, the present invention is characterized in that a tip portion of the liquid sealing lip member is formed to be a peak.

Thus, the tip portion of the liquid sealing lip member is formed like the peak. Consequently, even if the liquid sealing lip member comes in contact with the liquid treating surface of the surface treated substance, a contact area of the tip portion of the liquid sealing lip member and the liquid treating surface of the surface treated substance is reduced. Therefore, it is possible to prevent the infiltration of the treating solution without damaging the surface treated substance.

In addition, the air gap of the tip portion of the liquid sealing lip member and the liquid treating surface of the surface treated substance is reduced. Therefore, the liquid collection described above is easily generated between the tip portion of the liquid sealing lip member and the liquid treating surface of the surface treated substance. Thus, it is possible to enhance the infiltration blocking effect of the treating solution by the water sealing effect.

Furthermore, the present invention is characterized in that the liquid sealing lip member is formed by an elastic member.

When the liquid sealing lip member is formed by the elastic member, thus, it is possible to prevent the infiltration of the treating solution without damaging the surface treated substance even if the liquid sealing lip member comes in contact with the liquid treating surface of the surface treated substance. In addition, an original state can be returned immediately by the restoring force of the elastic member. Therefore, the treating solution infiltration blocking effect can always be maintained, and furthermore, an inexpensive formation can be achieved.

Moreover, the present invention is characterized in that the second infiltration preventing member includes an upper lip component and a lower lip component which are disposed to be opposed to each other on both sides with a surface of the surface treated substance interposed therebetween.

By such a structure, the upper lip component and the lower lip component can function as shielding members to prevent the treating solution floating like the mist from infiltrating into the treating solution contact prevention chamber beyond the liquid sealing lip member from a clearance in a place which is not covered with the liquid sealing lip member or the like.

In addition, a gap between the upper lip component and the lower lip component is minimized. Therefore, it is possible to reliably and effectively prevent the treating solution floating like the mist from infiltrating from the portion among the upper lip component, the lower lip component and the surface of the surface treated substance.

Furthermore, the present invention is characterized in that tip portions of the upper lip component and the lower lip component are formed to be peaks, respectively.

Thus, the tip portions of the upper lip component and the lower lip component are formed like the peaks, respectively. Consequently, the cross section areas among the tip portion of the upper lip component, the tip portion of the lower lip component and the surface of the surface treated substance are reduced, respectively. Even if the upper lip component and the lower lip component come in contact with the surface of the surface treated substance respectively, since the a contact area against the surface treated substance is reduced, it is possible to prevent the infiltration of the treating solution without damaging the surface treated substance.

In addition, the present invention is characterized in that at least one of the upper lip component and the lower lip component is formed by an elastic member.

When at least one of the upper lip component and the lower lip component is formed by the elastic member, thus, even if the upper lip component and the lower lip component come in contact with the liquid treating surface of the surface treated substance, respectively, it is possible to prevent the infiltration of the treating solution without damaging the surface treated substance. In addition, an original state can be returned immediately by the restoring force of the elastic member. Therefore, the treating solution infiltration blocking effect can always be maintained, and furthermore, an inexpensive formation can be achieved.

In addition, the present invention is characterized in that an inner part of the treating solution contact prevention chamber is constituted to be maintained in a pressurizing state.

Thus, the inside of the treating solution contact prevention chamber is maintained in a pressurizing state. Therefore, it is possible to reliably prevent the treating solution, which is discharged from the treating solution discharging device and then floating like the mist, from coming in contact with the surface treated substance with a difference in a pressure.

Moreover, the present invention is characterized in that the treating solution contact prevention chamber is provided on an upstream side of a liquid treating start position A to be a liquid treating terminal position and is constituted to prevent a discharged solution from coming in contact with the surface treated substance in a position on an upstream side of the liquid treating start position A.

By such a structure, the surface treated substance passes through the inside of the treating solution contact prevention chamber provided on the upstream side of the liquid treating start position A to be the liquid treating terminal position. Therefore, it is possible to prevent the discharged solution from coming in contact with the surface treated substance before the liquid treating start position A.

Accordingly, the discharged solution, which is discharged from the treating solution discharging device and floating like the mist can be prevented from coming in contact with the surface treated substance before the liquid treating start position A in an almost isolation state by the treating solution contact prevention chamber. Therefore, the treatment can be carried out reliably with the treating solution and a defective product can be prevented from being generated.

Furthermore, the present invention is characterized in that an end on an upstream side of a plate is inserted in an opening portion on an outlet side in the treating solution contact prevention chamber, which is positioned on a downstream side in a direction of delivery in the treating solution contact prevention chamber, and is positioned on an upstream side of the liquid treating chamber, and

there are disposed a first infiltration preventing member, between the end on the upstream side of the plate and the opening portion on the outlet side in the treating solution contact prevention chamber,

Which prevents the treating solution discharged from the treating solution discharging device and flowing to the upstream side along the surface treated substance, from infiltrating into the downstream side of the treating solution contact prevention chamber; and

a second infiltration preventing member for preventing the treating solution, which is discharged from the liquid discharging device and then floating in the chamber, from infiltrating into the downstream side of the treating solution contact prevention chamber; and

wherein the liquid treating apparatus includes a plate disposed below the treating solution discharging device and constituting a delivery surface of the surface treated substance.

By such a structure, the surface treated substance is maintained to be supported on the plate at the end on the upstream side of the plate in a position of the opening portion on the outlet side in the treating solution contact prevention chamber. Therefore, the surface treated substance is not flexed in that position. Consequently, the treating solution, which is flowing toward the upstream side along the surface treated substance, can be prevented reliably from infiltrating into the downstream side (outlet side) of the treating solution contact prevention chamber, by means of the first infiltration preventing member.

Moreover, the surface treated substance is thus maintained to be supported on the plate at the end on the upstream side of the plate. Therefore, the surface treated substance is not flexed in that position. Consequently, the treating solution floating in the chamber can be prevented reliably from infiltrating into the downstream side of the treating solution contact prevention chamber by means of the second infiltration preventing member.

By such a structure, the surface treated substance is delivered in a support state on the plate. Therefore, it is possible to prevent the gap among the first infiltration preventing member, the second infiltration preventing member and the surface of the surface treated substance from being enlarged due to the flexure of the surface treated substance.

Accordingly, the treating solution, which is discharged from the treating solution discharging device and flowing along the liquid treating surface of the surface treated substance and the treating solution, which is discharged from the treating solution discharging device and then floating like the mist, can be prevented reliably from coming in contact with the surface treated substance.

In addition, the present invention is characterized in that the treating solution contact prevention chamber is provided on a downstream side of a liquid treating end position B to be a liquid treating terminal position and is constituted to prevent the discharged solution from coming in contact with the surface treated substance in a position on a downstream side of a liquid treating end position B.

By such a structure, the discharged solution passes through the inside of the treating solution contact prevention chamber provided on the downstream side of the liquid treating end position B to be the liquid treating terminal position. Therefore, it is possible to prevent the discharged solution from coming in contact with the surface treated substance after the liquid treating end position B.

Consequently, the etchant floating like the mist can be prevented from excessively treating the surface of the surface treated substance in contact therewith. Thus, a defective product can be prevented from being generated.

Moreover, the present invention is characterized in that an end on a downstream side of a plate is inserted in an opening portion on an inlet side in the treating solution contact prevention chamber, which is positioned on an upstream side in a direction of delivery in the treating solution contact prevention chamber, and positioned on a downstream side of the liquid treating chamber, and

there are disposed a first infiltration preventing member, between the end on the downstream side of the plate and the opening portion on the inlet side in the treating solution contact prevention chamber,

Which prevents the treating solution discharged from the treating solution discharging device and flowing to the downstream side along the surface treated substance, from infiltrating into the upstream side of the treating solution contact prevention chamber; and

a second infiltration preventing member for preventing the treating solution, which is discharged from the liquid discharging device and then floating in the chamber, from infiltrating into the upstream side of the treating solution contact prevention chamber.

By such a structure, the surface treated substance is maintained to be supported on the plate at the end on the downstream side of the plate in a position of the opening portion on the inlet side in the treating solution contact prevention chamber. Therefore, the surface treated substance is not flexed in that position. Consequently, the treating solution flowing toward the downstream side along the surface treated substance can be prevented reliably from infiltrating into the upstream side (inlet side) of the treating solution contact prevention chamber, by means of the first infiltration preventing member.

Moreover, the surface treated substance is thus maintained to be supported on the plate at the end on the downstream side of the plate. Therefore, the surface treated substance is not flexed in that position. Consequently, the treating solution floating in the chamber can be prevented reliably from infiltrating into the upstream side (inlet side) of the treating solution contact prevention chamber, by means of the second infiltration preventing member.

In addition, the present invention is characterized in that the surface treated substance is a film carrier tape for mounting electronic component.

Thus, in the case in which the surface treated substance is a film carrier tape and the treating solution is an etchant, for example, the mist-like etchant can be prevented from splashing before the etching treatment. Thus, there is no possibility that stains, a disconnection of a wiring pattern, a short circuit and the like might be generated.

### EFFECT OF THE INVENTION

The surface treated substance passes through the inside of the treating solution contact prevention chamber, which is disposed in the outer position in the direction of the delivery of the surface treated substance from the liquid treating terminal position, for example, the inside of the treating solution contact prevention chamber, which is disposed on the upstream side of the liquid treating start position A to be the liquid treating terminal position. Therefore, it is possible to prevent the discharged solution from coming in contact with the surface treated substance before the liquid treating start position A.

Accordingly, the solution, which is discharged by means of the treating solution discharging device and floating like a mist, can be prevented from coming in contact with the surface treated substance before the liquid treating start position A, in a state in which the discharged solution is almost isolated through the treating solution contact prevention chamber. Consequently, it is possible to reliably carry out a treatment with the treating solution. Thus, it is possible to prevent a defective product from being generated.

Moreover, the surface treated substance passes through the inside of the treating solution contact prevention chamber, which is disposed in the outer position in the direction of the delivery of the surface treated substance from the liquid treating terminal position, for example, the inside of the treating solution contact prevention chamber, which is disposed on the downstream side of the liquid treating end position B to be the liquid treating terminal position. Therefore, it is possible to prevent the discharged solution from coming in contact with the surface treated substance after the liquid treating end position B.

Consequently, it is possible to prevent the etchant floating like the mist from excessively treating the surface of the surface treated substance in contact therewith. Thus, it is possible to prevent a defective product from being generated.

Furthermore, the first infiltration preventing member can prevent the treating solution, which is discharged from the treating solution discharging device and flowing along the liquid treating surface of the surface treated substance, from infiltrating into the treating solution contact prevention chamber.

Furthermore, the second infiltration preventing member is disposed on the further inside of the treating solution contact prevention chamber from of the first infiltration preventing member, so that the treating solution, which is discharged from the treating solution discharging device and is then floating like the mist, can be prevented from infiltrating into the treating solution contact prevention chamber.

More specifically, a cutoff is carried out doubly in a sense in such a manner that the first infiltration preventing member can prevent the flowing treating solution from infiltrating into the treating solution contact prevention chamber and the second infiltration preventing member can prevent the treating solution floating like the mist from infiltrating into the treating solution contact prevention chamber.

Accordingly, it is possible to reliably prevent the discharged solution from coming in contact with the surface treated substance and to surely carry out a treatment with the treating solution. Thus, it is possible to prevent a defective product from being generated.

In particular, in the case in which the surface treated substance is a film carrier tape for mounting electronic component and the treating solution is an etchant, for example, the mist-like etchant can be prevented from splashing before the etching treatment. Thus, there is no possibility that stains, a disconnection of a wiring pattern, a short circuit and the like might be generated.

### BRIEF DESCRIPTION OF THE DRAWINGS

FIG. 1 is a schematic view showing an example in which a liquid treating apparatus according to the present invention is applied to a device for etching a film carrier tape for mounting electronic component,

FIG. 2 is a schematically partial enlarged view of FIG. 1,

FIG. 3 is a schematic view showing another example in which the liquid treating apparatus according to the present invention is applied to the device for etching a film carrier tape for mounting electronic component,

FIG. 4 is a schematic view showing a device for etching a film carrier tape for mounting electronic component according to the conventional example,

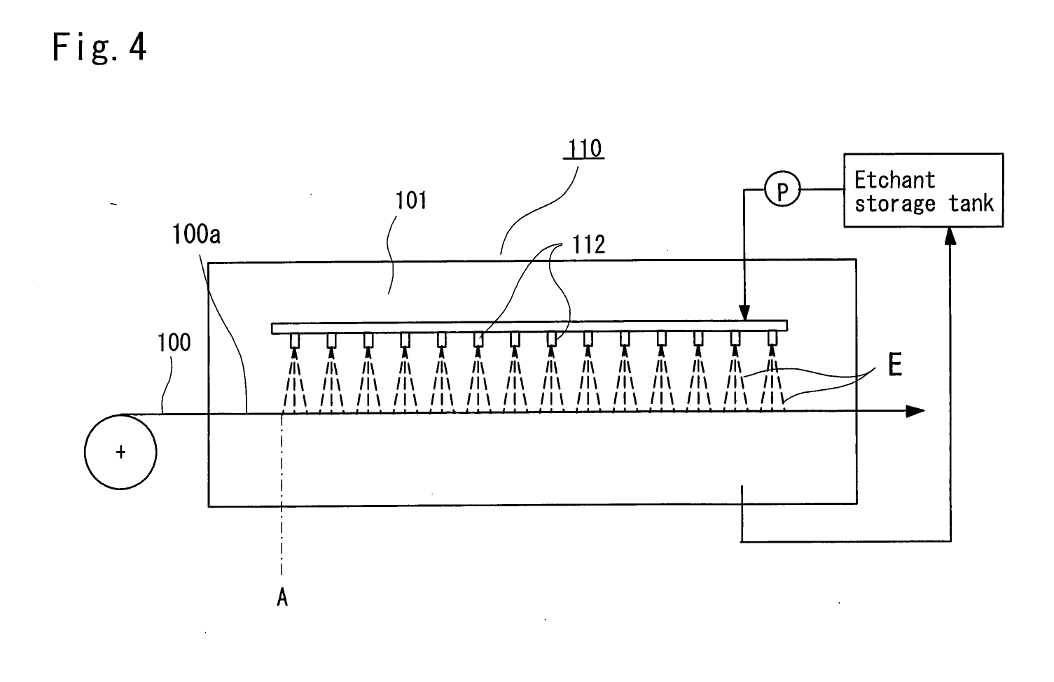

FIG. 5 is a partially enlarged sectional view showing a desirable wiring section,

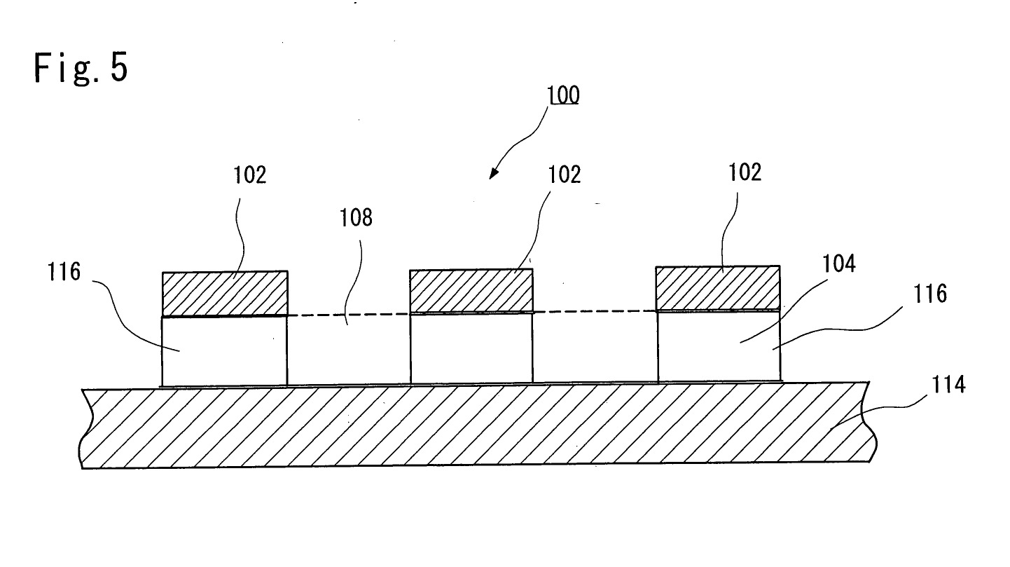

FIG. 6 is a partially enlarged sectional view showing a wiring section manufactured by the conventional etching treatment,

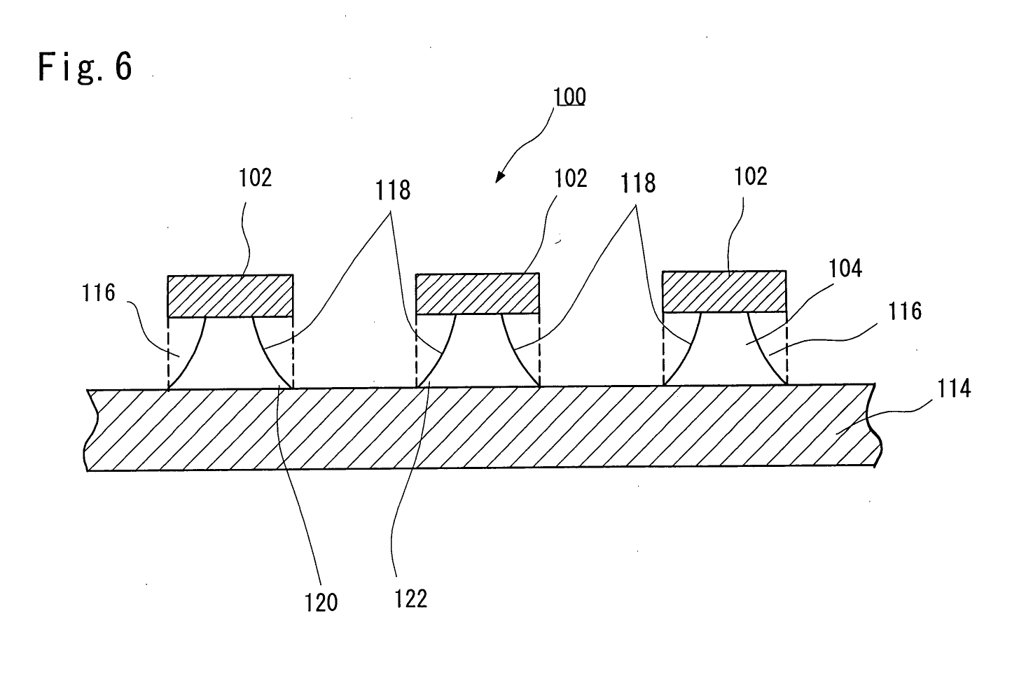

FIG. 7 is a partially enlarged sectional view showing a desirable wiring section, and

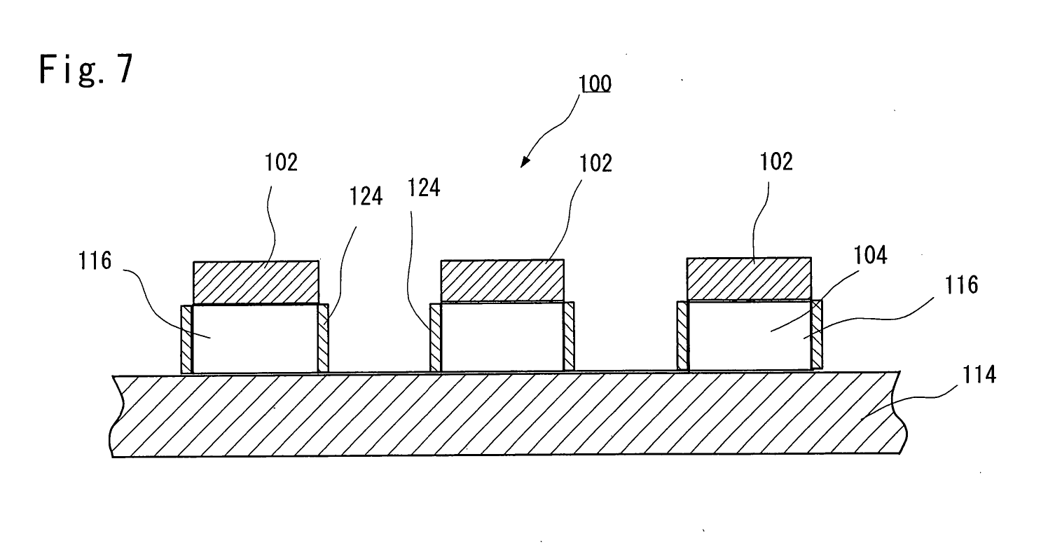

FIG. 8 is a partially enlarged sectional view showing the wiring section which the short circuit has generated in the wiring pattern.

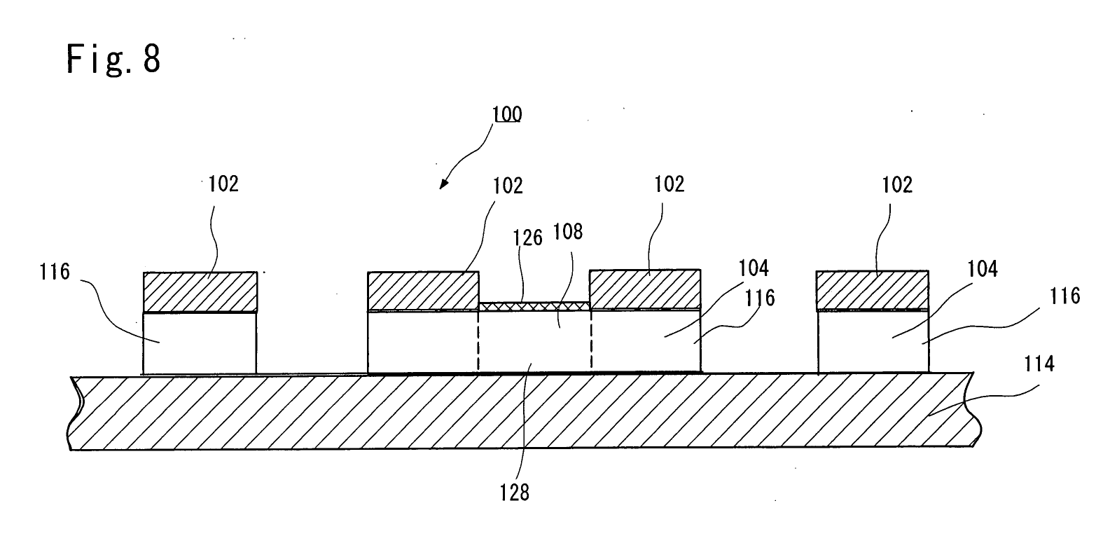

### DETAILED DESCRIPTION OF THE PREFERRED EMBODIMENT

An embodiment (example) of the present invention will be described below in more detail with reference to the drawings.

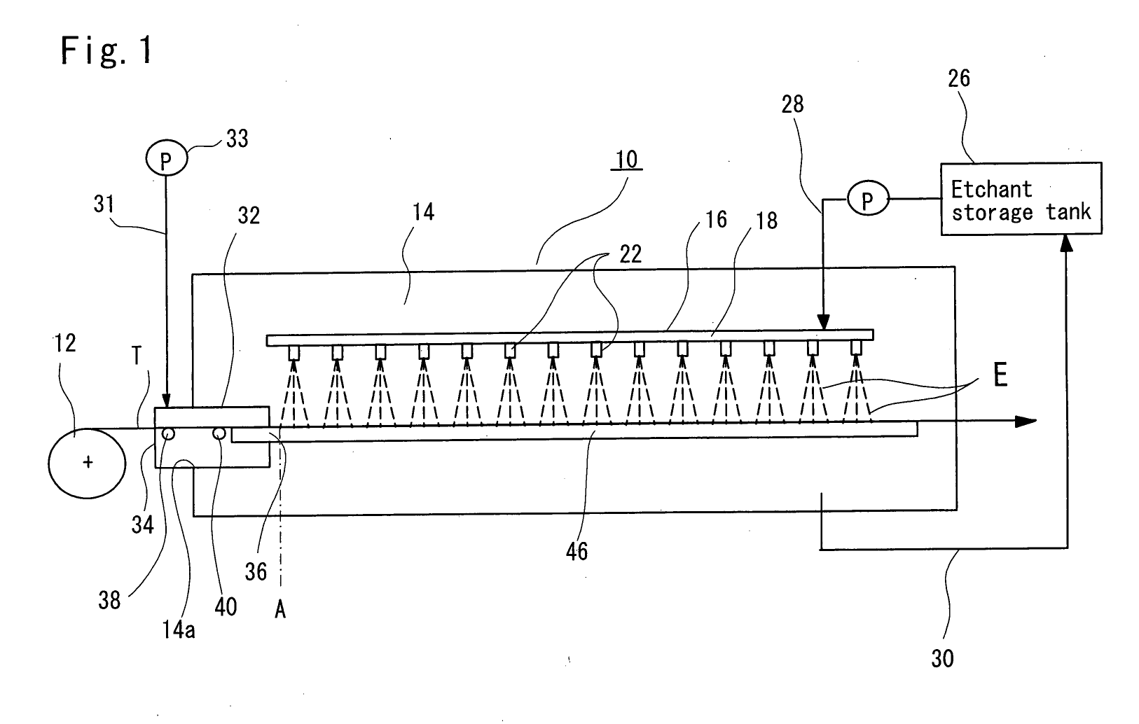

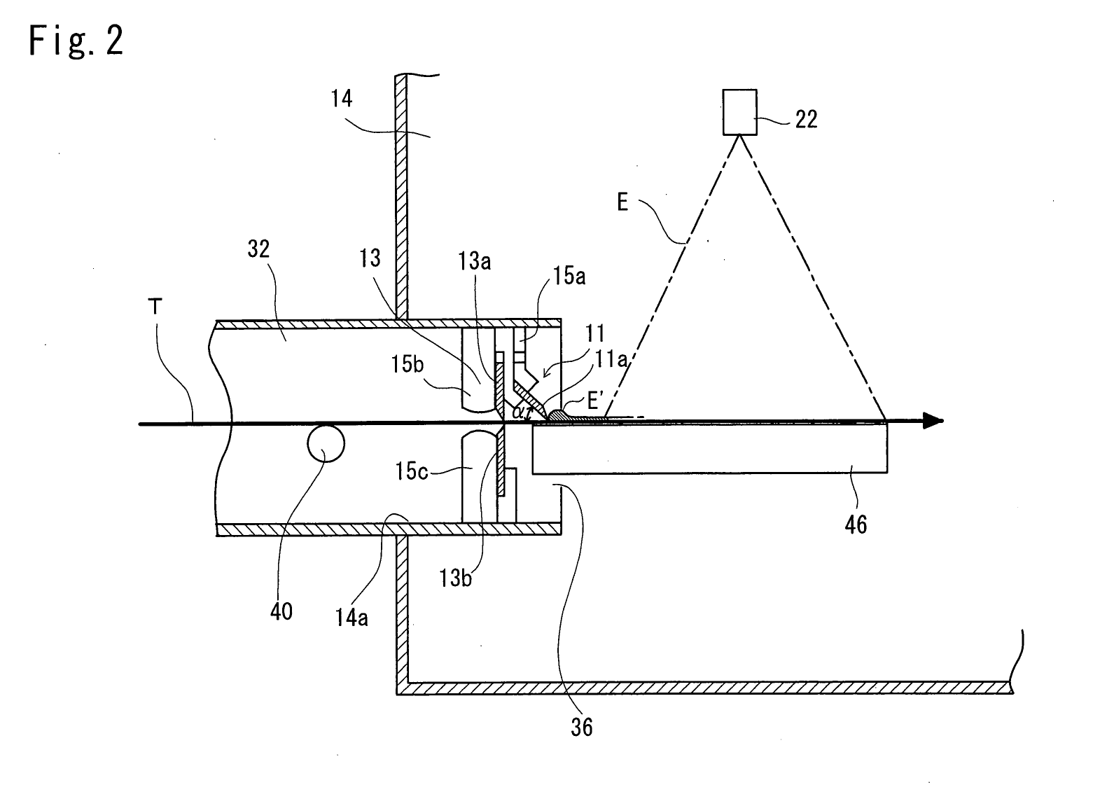

FIG. 1 is a schematic view showing an example in which a liquid treating apparatus according to the present invention is applied to a device for etching a film carrier tape for mounting electronic component to be a sheet-like substance to be surface treated, and FIG. 2 is a schematically partial enlarged view.

In FIGS. 1 and 2, 10 denotes a device for etching a film carrier tape according to the present invention (which will be hereinafter referred to as an “etching device”) as a whole.

The etching device 10 is used as a substance to be surface treated, that is, a film carrier tape T formed by exposing a desirable pattern shape through the irradiation of an ultraviolet ray onto a photoresist by means of a photomask and dissolving and removing the exposed photoresist portion with a developer, thereby exposing a copper layer portion which is not covered with the photoresist.

The etching device 10 comprises a feed roll 12 around which the film carrier tape T which has not been treated with a liquid is wound.

Moreover, an etching plate 46 for holding a delivery posture of the sheet-like film carrier tape T in a delivery direction is provided in the etching chamber 14.

The film carrier tape T is continuously fed from the feed roll 12 to the etching chamber 14 in the etching device 10 and the copper layer portion which is not covered with the photoresist is removed with an etchant (acid) over the etching plate 46 so that a wiring pattern is formed by a copper layer remaining on an insulating film.

Then, the film carrier tape T passing through the etching chamber 14 in the etching device 10 is subjected to the dissolution and removal of a photoresist with an alkali solution, the formation of a solder resist layer, the plating of a lead portion and the like so that a film carrier tape is finally manufactured in the same manner as in the conventional art.

An etchant discharging device 16 is provided above the film carrier tape T in the etching chamber 14 of the etching device 10.

The etchant discharging device 16 is provided with an etchant transportation piping 18 extended in the direction of the delivery of the film carrier tape T. The etchant transportation piping 18 has a plurality of etchant discharging nozzles 22, which is disposed apart from each other at a predetermined interval in the direction of the feed of the film carrier tape T.

An etchant E is supplied at a constant pressure from an etchant storage tank 26 to the etchant transportation piping 18 through a pump P and an etchant supply tube 28, and furthermore, is discharged from the etchant discharging nozzle 22 to an upper surface of the film carrier tape T passing through the inside of the etching chamber 14.

Moreover, the etchant E discharged from the etchant discharging nozzle 22 to the upper surface of the film carrier tape T properly passes through a reproducing device (not shown) or the like via a collection piping 30 from the etching chamber 14 and is then recycled into the etchant storage tank 26.

Usually, a part of the etchant discharged from the etchant discharging nozzle 22 is changed like a mist and floats in the etching chamber 14. For this reason, in some cases, a mist-like etchant E″ splashes over the film carrier tape T portion on an upstream side of a liquid treating start position A for the etchant E supplied from the etchant discharging nozzle 22. In these cases, there is a possibility that stains, a disconnection of a wiring pattern, a short circuit and the like are generated.

Therefore, in the etching device 10 according to the present invention, as shown in FIGS. 1 and 2, a treating solution contact prevention chamber 32 is disposed in an outer position in a direction of delivery of the surface treated substance (the film carrier tape T) from a liquid treating terminal position, that is, a position on the upstream side of the liquid treating start position A for the etchant to be the liquid treating terminal position in the present example.

By providing the treating solution contact prevention chamber 32, it is possible to prevent the mist-like etchant E″ from coming in contact with the film carrier tape T on the upstream side of the liquid treating start position A (in a previous stage).

More specifically, for example, as shown in an enlarged view of FIG. 2, the treating solution contact prevention chamber 32 is barrel-shaped with a section which is flat and square and both ends which are almost sealed, and one end thereof is penetrated through an upstream side opening portion 14a of the etching chamber 14 and extended to the vicinity of the liquid treating start position A. As shown in FIG. 1, an inlet side opening portion 34 on an upstream side and an outlet side opening portion 36 on a downstream side in the treating solution contact prevention chamber 32 are formed to have small opening widths in such a manner that the film carrier tape T can pass therethrough, respectively.

In this case, the shape of the treating solution contact prevention chamber 32 which is a barrel is not particularly restricted but various shapes such as a cylindrical shape or a triangularly cylindrical shape can also be applied.

Moreover, for example, in the etching device 10 according to the present example, the film carrier tape T is fed to the treating solution contact prevention chamber 32. Thereafter, the film carrier tape T is delivered by means of guide rollers 38 and 40 in the treating solution contact prevention chamber 32 and is then supplied from the outlet side opening portion 36 on the downstream side of the treating solution contact prevention chamber 32 into the etching chamber 14.

In FIGS. 1 and 2, the etching plate 46 is disposed below the etchant discharging device 16. The etching plate 46 serves to support the film carrier tape T in order to prevent the film carrier tape T, which is supplied from the outlet side opening portion 36 of the treating solution contact prevention chamber 32 into the etching chamber 14, from being hung downward at a discharge pressure of the etchant E discharged from the etchant discharging nozzle 22 of the etchant discharging device 16, resulting in no execution of an accurate etching treatment.

The etching plate 46 has a width which is greater than a width of the film carrier tape T and is smaller than a width between side walls in a transverse direction of the treating solution contact prevention chamber 32.

Consequently, as will be described below, an etchant E′ set in a liquid collection state can flow down to a bottom portion of the treating solution contact prevention chamber 32 from both ends in the transverse direction of the etching plate 46.

By providing the treating solution contact prevention chamber 32, the film carrier tape T portion on the upstream side of the liquid treating start position A is covered and shielded with the treating solution contact prevention chamber 32. Therefore, it is possible to prevent a mist-like etchant E″ from splashing over the film carrier tape T portion disposed on the upstream side of the liquid treating start position A. Consequently, stains, a disconnection of a wiring pattern, a short circuit and the like are prevented from being generated in the film carrier tape T portion disposed on the upstream side of the liquid treating start position A.

Furthermore, a first infiltration preventing member 11 and a second infiltration preventing member 13 are provided in the treating solution contact prevention chamber 32 according to the present example, in such a manner that the etchant E and the mist-like etchant E″ can be prevented from carelessly infiltrating thereinto as shown in FIG. 2.

Moreover, the second infiltration preventing member 13 is disposed on an inner side of the treating solution contact prevention chamber 32 from the first infiltration preventing member 11.

The first infiltration preventing member 11 includes a liquid sealing lip member 11a attached removably to an upper wall of the treating solution contact prevention chamber 32 through a bracket 15a as shown in FIG. 2.

It is desirable that the liquid sealing lip member 11a should have a width which is greater than the width of the etching plate 46 and is almost coincident with the width between the side walls in the transverse direction of the treating solution contact prevention chamber 32 in order to prevent the etchant E″ floating like the mist in the chamber from infiltrating into the treating solution contact prevention chamber 32 by means of the shield of a body portion of the liquid sealing lip member 11a.

However, there is employed a structure in which the second infiltration preventing member 13 is disposed and the etchant E″ floating like the mist in the chamber is prevented from infiltrating into the treating solution contact prevention chamber 32. Therefore, the width of the liquid sealing lip member 11a may be almost coincident with that of the etching plate 46.

On the other hand, the second infiltration preventing member 13 is constituted by two members having an upper lip component 13a disposed on an upper side and a lower lip component 13b disposed on a lower side in order to be opposed to each other at both sides with a delivery surface of the film carrier tape T interposed therebetween.

Moreover, the upper lip component 13a is removably attached to an upper wall of the treating solution contact prevention chamber 32 through a bracket 15b. Furthermore, the lower lip component 13b is removably attached to a lower wall of the treating solution contact prevention chamber 32 through a bracket 15c.

It is desirable that the upper lip component 13a and the lower lip component 13b should have widths which are almost coincident with the width between the side walls in the transverse direction of the treating solution contact prevention chamber 32 in order to prevent the treating solution E″ floating like the mist in the chamber from infiltrating into the treating solution contact prevention chamber 32.

The bracket 15a for holding the liquid sealing lip member 11a and the bracket 15b for holding the upper lip component 13a are constituted to be integral in the present example. However, these brackets 15a and 15b can also be disposed apart from each other depending on a distance between the liquid sealing lip member 11a and the upper lip component 13a.

Moreover, the liquid seating lip member 11a is disposed in an inclination posture so as to be inclined to a liquid treating surface side of the film carrier tape T which is a substance to be surface treated, toward the liquid treating start position A side to be a liquid treating terminal position side, that is, the outlet side opening portion 36 of the treating solution contact prevention chamber 32 as shown in FIG. 2.

In this case, an inclination angle α between the liquid sealing lip member 11a and the liquid treating surface of the film carrier tape T which is the surface treated substance is 5 to 135 degrees, and preferably 30 to 90 degrees. More specifically, in some cases in which the angle is smaller than 5 degrees, the liquid is drawn in by a capillary phenomenon.

If the inclination angle α formed between the liquid sealing lip member 11a and the liquid treating surface of the film carrier tape T is present within such a range, the liquid sealing lip member 11a and the liquid treating surface of the film carrier tape T are disposed mutually with some angle. Therefore, a liquid collection which will be described below is easily generated between a tip portion of the liquid sealing lip member 11a and the liquid treating surface of the film carrier tape T. Consequently, it is possible to enhance a treating solution infiltration blocking effect obtained by a water sealing effect.

Moreover, the tip portion of the liquid sealing lip member 11a is cut obliquely and is thus formed like a peak. It is preferable that an interval between the tip portion of the liquid sealing lip member 11a and the film carrier tape T should be approximately 1 mm.

In the present example, the liquid sealing lip member 11a is thus inclined and disposed like the peak. Consequently, the treating solution E discharged from the liquid discharging nozzle 22 onto the upper surface of the film carrier tape T can be hindered effectively from infiltrating to the inner side of the treating solution contact prevention chamber.

More specifically, the first infiltration preventing member 11 includes the lip-shaped liquid sealing lip member 11a. By a shield through the body portion of the liquid sealing lip member 11a, consequently, it is possible to prevent the treating solution E″, which is discharged from the etchant discharging device 16 and then floating like the mist in the chamber, from infiltrating into the treating solution contact prevention chamber 32.

Moreover, the treating solution E, which is discharged from the liquid discharging nozzle 22 of the etchant discharging device 16 onto the upper surface of the film carrier tape T, is changed into the treating solution E′ flowing along the upper surface of the film carrier tape T.

The treating solution E′, which is flowing along the upper surface of the film carrier tape T in a flowing state, tries to flow into the treating solution contact prevention chamber 32, and comes in contact with the tip portion of the liquid sealing lip member 11a between the tip portion of the liquid sealing lip member 11a and the liquid treating surface of the film carrier tape T as shown in FIG. 2. Consequently, a surface tension is applied so that a liquid collection is generated. The liquid collection brings a so-called water sealing state so that the infiltration can be prevented by the water sealing effect.

In addition, a portion between the tip portion of the liquid sealing lip member 11a and the liquid treating surface of the film carrier tape T is thus sealed with the liquid collection of the treating solution. Consequently, it is also possible to prevent the treating solution E″, which is floating like the mist from infiltrating from the portion between the tip portion of the liquid sealing lip member 11a and the liquid treating surface of the film carrier tape T, from infiltrating into the treating solution contact prevention chamber 32.

In this case, moreover, the direction of the delivery of the film carrier tape T is also set apart from the portion between the tip portion of the liquid sealing lip member 11a and the liquid treating surface of the film carrier tape T. Also in this respect, therefore, it is possible to prevent the treating solution E from infiltrating into the treating solution contact prevention chamber 32.

Thus, the liquid sealing lip member 11a blocks the infiltration into the treating solution contact prevention chamber 32 and the treating solution E′ set in the collecting state flows down into the bottom portion of the etching chamber 14 from both ends in the transverse direction of the etching plate 46.

In this case, the inside of the bottom portion of the treating solution contact prevention chamber 32 is shielded with the lower lip component 13b and the bracket 15c for holding the lower lip component 13b.

Accordingly, the treating solution E, which is dropping into the outer bottom portion of the treating solution contact prevention chamber 32, does not infiltrate into the treating solution contact prevention chamber 32 but is recycled into the etchant storage tank 26 through the outlet side opening portion 36 of the treating solution contact prevention chamber 32, the etching chamber 14 and the collection piping 30.

In this case, it is desirable that the tip portion of the liquid sealing lip member should be formed to be the peak.

Thus, the tip portion of the liquid sealing lip member 11a is formed to be the peak so that the cross section area of the tip portion of the liquid sealing lip member 11a is reduced. Consequently, even if the liquid sealing lip member comes in contact with the liquid treating surface of the surface treated substance, a contact area of the tip portion of the liquid sealing lip member 11a and the liquid treating surface of the film carrier tape T is reduced. Therefore, it is possible to prevent the treating solution from infiltrating without damaging the surface treated substance.

In addition, the air gap of the tip portion of the liquid sealing lip member 11a and the liquid treating surface of the film carrier tape T is reduced. Consequently, the liquid collection is easily generated between the tip portion of the liquid sealing lip member 11a and the liquid treating surface of the film carrier tape T. Thus, it is possible to enhance the infiltration blocking effect of the treating solution by the water sealing effect.

Moreover, it is desirable that the liquid sealing lip member 11a should be formed by an elastic member such as a rubber or a resin which can easily be deformed elastically.

When the liquid sealing lip member 11a is formed by the elastic member, thus, even if the liquid sealing lip member 11a comes in contact with the liquid treating surface of the film carrier tape T, it is possible to prevent the treating solution from infiltrating without damaging the film carrier tape T, and furthermore, to immediately return to an original state by the restoring force of the elastic member. Consequently, the treating solution infiltration blocking effect can be always maintained, and furthermore, an inexpensive formation can be carried out.

On the other hand, a part of the treating solution E discharged from the liquid discharging nozzle 22 floats in the mist state in the etching chamber 14.

Accordingly, a part of the treating solution E″ floating like the mist tries to get across the liquid sealing lip member from a clearance of a portion which is not covered with the liquid sealing lip member 11a or the like and to infiltrate into the treating solution contact prevention chamber 32.

However, the upper lip component 13a and the lower lip component 13b are disposed to be opposed to each other from above and below, respectively. Therefore, the upper lip component 13a and the lower lip component 13b can function as shielding members to prevent the floating treating solution E″ from getting over the second infiltration preventing member 13, that is, the upper lip component 13a and the lower lip component 13b to infiltrate into the treating solution contact prevention chamber 32.

In addition, a clearance between the upper lip component 13a and the lower lip component 13b is minimized. Therefore, it is possible to reliably and effectively prevent the treating solution E″ floating like the mist from infiltrating from a portion among the upper lip component 13a, the lower lip component 13b and the surface of the film carrier tape T.

As shown in FIG. 2, furthermore, the tip portions of the upper lip component 13a and the lower lip component 13b are formed like peaks, respectively.

Thus, the tip portions of the upper lip component 13a and the lower lip component 13b are formed like the peaks, respectively. Consequently, even if the upper lip component 13a and the lower lip component 13b come in contact with the surface of the film carrier tape T respectively, the contact areas among the tip portion of the upper lip component 13a, the tip portion of the lower lip component 13b and the surface of the film carrier tape T are reduced, respectively. Therefore, it is possible to prevent the treating solution from infiltrating without damaging the film carrier tape T.

Moreover, it is desirable that at least one of the upper lip component 13a and the lower lip component 13b should be formed by an elastic member such as a rubber or a resin which can easily be deformed elastically.

Thus, when at least one of the upper lip component 13a and the lower lip component 13b is formed by the elastic member, even if the upper lip component 13a and the lower lip component 13b come in contact with the surface of the film carrier tape T, respectively, it is possible to prevent the treating solution from infiltrating without damaging the film carrier tape T, and furthermore, to immediately return to an original state by the restoring force of the elastic member. Therefore, the treating solution infiltration blocking effect can be always maintained, and furthermore, an inexpensive formation can be carried out.

Moreover, the etching device 10 according to the present example includes the etching plate 46. Therefore, the film carrier tape T is delivered in a support state by the etching plate 46.

Consequently, the gap among the liquid sealing lip member 11a of the first infiltration preventing member 11, the upper lip component 13a and the lower lip component 13b of the second infiltration preventing member 13, and the surface of the film carrier tape T can be prevented from being enlarged due to the flexure of the film carrier tape T.

Accordingly, the treating solution E′, which is discharged from the liquid discharging nozzle 22 of the etchant discharging device 16 and flowing along the liquid treating surface of the film carrier tape T and the treating solution E″, which is discharged from the etchant discharging device 16 and then floating like the mist, can be reliably prevented from coming in contact with the film carrier tape T.

According to the present example, the liquid sealing lip member 11a of the first infiltration preventing member 11 and the upper lip component 13a and the lower lip component 13b of the second infiltration preventing member 13 are disposed in the treating solution contact prevention chamber 32. Thus, it is possible to prevent the treating solution E and the mist E″ from carelessly infiltrating into the treating solution contact prevention chamber 32. Consequently, it is possible to reliably prevent the treating solutions E, E′ and E″ from carelessly splashing over the upper surface of the film carrier tape T delivered from the upstream side. Therefore, it is possible to prevent the generation of stains, a disconnection of a wiring pattern, a short circuit and the like.

More specifically, the treating solution E′, which is discharged from the liquid discharging nozzle 22 of the etchant discharging device 16 and flowing along the film carrier tape T, can be prevented from infiltrating into the treating solution contact prevention chamber 32 by means of the liquid sealing lip member 11a of the first infiltration preventing member 11.

The treating solution E″, which is discharged from the liquid discharging nozzle 22 of the etchant discharging device 16 and flowing like the mist, can be prevented from infiltrating into the treating solution contact prevention chamber 32, by means of the upper lip component 13a and the lower lip component 13b in the second infiltration preventing member 13, which is disposed on the inner part of the treating solution contact prevention chamber 32 from the first infiltration preventing member 11.

More specifically, a cutoff is carried out doubly in a sense in such a manner that, the first infiltration preventing member can prevent the treating solution E′, which is flowing along the treated surface of the film carrier tape T, from infiltrating into the treating solution contact prevention chamber 32, and the upper lip component 13a and the lower lip component 13b in the second infiltration preventing member 13 can prevent the treating solution E″ floating like the mist from infiltrating into the treating solution contact prevention chamber 32.

Accordingly, it is possible to reliably prevent the discharged solution from coming in contact with the film carrier tape T and to surely carry out a treatment with the treating solution. Thus, it is possible to prevent a defective product from being generated.

Furthermore, in the etching device 10 according to the present example, as shown in FIG. 1, a compressed air supply line 31 is connected to the upstream side of the treating solution contact prevention chamber 32 in the etching chamber 14 and a pressurizing device 33 including a filter for supplying the compressed air is connected to the compressed air supply line 31. By such a pressurizing device 33, the compressed air can also be supplied into the treating solution contact prevention chamber 32.

If the compressed air is thus introduced into the treating solution contact prevention chamber 32, for example, the inner part of the treating solution contact prevention chamber 32 can be maintained in a pressurizing state.

By pressurizing the inner part of the treating solution contact prevention chamber 32, thus, a difference in a pressure is made between the treating solution contact prevention chamber 32 and the etching chamber 14. Consequently, the discharged solution E″ floating like the mist in the etching chamber 14 can be prevented from infiltrating into the treating solution contact prevention chamber 32.

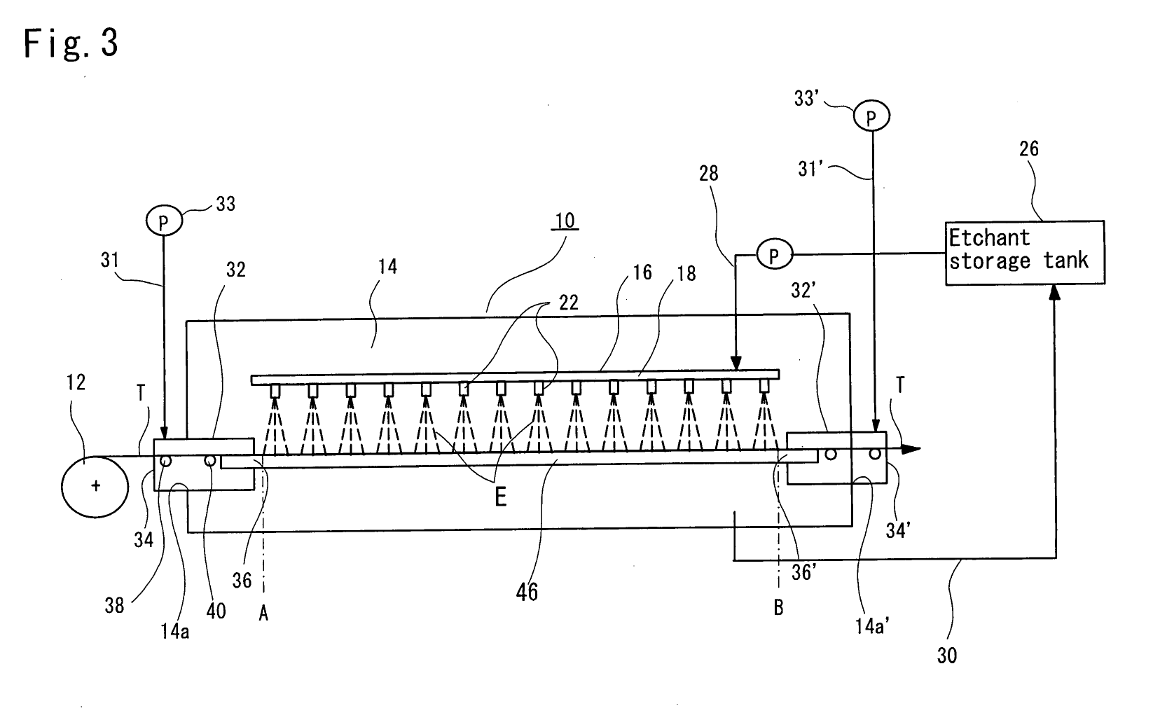

FIG. 3 is a schematic view showing another example in which the liquid treating apparatus according to the present invention is applied to a device for etching a film carrier tape for mounting electronic component.

The etching device 10 according to the present example has basically the same structure as that shown in FIGS. 1 and 2, and the same components have the same reference numerals. The same components as those in the treating solution contact prevention chamber 32 have “′” and detailed description thereof will be omitted.

In the etching device 10 according to the present example, as shown in FIG. 3, a treating solution contact prevention chamber 32′ on a downstream side, which has the same structure as the structure of the treating solution contact prevention chamber 32, is disposed in an outer position in the direction of the delivery of the film carrier tape T from a liquid treating terminal position, that is, on a downstream side of a liquid treating end position B to be a liquid treating terminal position of the treating solution in the etchant discharging device 16 in the present example.

Also in the treating solution contact prevention chamber 32′ on the downstream side, a liquid sealing lip member 11a′ of a first infiltration preventing member 11′ and an upper lip component 13a′ and a lower lip component 13b′ in a second infiltration preventing member 13′ are disposed in the same manner as the treating solution contact prevention chamber 32, which is not shown.

More specifically, an end on a downstream side of an etching plate 46 is inserted into an inlet side opening portion 36′ in a treating solution contact prevention chamber 32′ which is positioned on an upstream side in the direction of delivery in the treating solution contact prevention chamber 32′ and a downstream side of an etching chamber 14.

The liquid sealing lip member 11a′ of the first infiltration preventing member 11′ is provided between the end on the downstream side of the etching plate 46 and the opening portion 36′ on the inlet side of the treating solution contact prevention chamber 32′. The liquid sealing lip member 11a′ serves to prevent a treating solution, which is discharged from a liquid discharging nozzle 22 of the etchant discharging device 16 and flowing to the downstream side along the film carrier tape T, from infiltrating into the downstream side of the treating solution contact prevention chamber 32′.

Furthermore, the upper lip component member 13a′ and the lower lip component 13b′ of the second infiltration preventing member 13′ are disposed on the downstream side of the first infiltration preventing member 11′. They serve to prevent the treating solution, which is discharged from the liquid discharging nozzle 22 of the etchant discharging device 16 and then floating in the etching chamber 14, from infiltrating into the downstream side of the treating solution contact prevention chamber 32′.

By providing the treating solution contact prevention chamber 32′ on the downstream side, thus, it is possible to prevent an etchant E″ floating like a mist from coming in contact with a surface of the film carrier tape T, which is subjected to a predetermined liquid treatment by the treating solution supplied from the etchant discharging device 16, thereby excessively treating a surface of a substance to be surface treated. Thus, it is possible to prevent the generation of a defective product.

While both the treating solution contact prevention chamber 32 and the treating solution contact prevention chamber 32′ are provided in the present example, only the treating solution contact prevention chamber 32′ can also be provided.

While the preferred embodiment of the present invention has been described above, the present invention is not restricted thereto.

Although the present invention has been applied to the device for etching a film carrier tape for mounting electronic component which uses an etchant containing a side etching inhibiting additive for reacting to copper to generate a slightly soluble compound in the example, for example, it can also be applied to an etching device using an ordinary etchant. In addition, it can also be applied to a process for discharging another treating solution to a space under pressure, for example, a liquid treating process such as a rinsing step, an acid washing step and the like after the liquid treatment.

Moreover, while the film carrier tape for mounting electronic component T has been used as the surface treated substance in the examples, the present invention can also be applied to other substances to be surface treated such as a rigid printed wiring board and a flexible printed circuit board in place thereof. Moreover, the film carrier tape for mounting electronic component T itself has been constituted to be delivered over the upper surface of the etching plate 46 in the examples. If the surface treated substance is another article, a delivery device such as a conveyer may be provided separately in order to deliver the article thereover if necessary.

Furthermore, while the compressed air is supplied into the treating solution contact prevention chamber 32 through the compressed air supply line 31, thereby pressurizing the inner part of the treating solution contact prevention chamber 32 in the examples, it is also possible to prevent the inner part of the treating solution contact prevention chamber 32 from being pressurized.

Moreover, while the present invention has been used in the case in which the film carrier tape T is delivered in the horizontal direction in the examples, it can also be used in the case in which the film carrier tape T is delivered in the vertical direction to discharge the etchant from the etchant discharging device 16 in the horizontal direction. Thus, various changes can be made without departing from the scope of the present invention.

What is claimed is:

1. A liquid treating apparatus for carrying out a predetermined liquid treatment for a substance to be surface treated which is supplied continuously, comprising:
a treating solution discharging device for discharging a treating solution to a liquid treating surface of the surface treated substance; and
a treating solution contact prevention chamber, which is provided in an outer position in a direction of delivery of the surface treated substance from a liquid treating terminal position, in which the treating solution is discharged to the liquid treating surface of the surface treated substance by means of the treating solution discharging device, and
which serves to prevent the discharged solution from coming in contact with the surface treated substance in an outer position in the direction of the delivery of the surface treated substance from the liquid treating terminal position,
the treating solution contact prevention chamber comprising:
a first infiltration preventing member disposed on the liquid treating terminal position side of the treating solution contact prevention chamber and serving to prevent the treating solution, which is discharged from the treating solution discharging device and flowing along the liquid treating surface of the surface treated substance, from infiltrating into the treating solution contact prevention chamber; and
a second infiltration preventing member disposed on an inside of the treating solution contact prevention chamber from the first infiltration preventing member and serving to prevent the treating solution, which is discharged from the treating solution discharging device and then floating in a chamber, from infiltrating into the treating solution contact prevention chamber; and
wherein the liquid treating apparatus serves to carry out a predetermined liquid treatment in a liquid treating chamber to be a limited space for the surface treated substance.

2. The liquid treating apparatus according to claim 1, wherein the first infiltration preventing member includes a liquid sealing lip member.

3. The liquid treating apparatus according to claim 2, wherein the liquid sealing lip member is disposed to be inclined to the liquid treating surface side of the surface treated substance toward the liquid treating terminal position side and is constituted to prevent the treating solution from infiltrating into the treating solution contact prevention chamber through the liquid treating surface of the surface treated substance.

4. The liquid treating apparatus according to claim 3, wherein an inclination angle α between the liquid sealing lip member and the liquid treating surface of the surface treated substance is 5 to 135 degrees.

5. The liquid treating apparatus according to claim 2, wherein a tip portion of the liquid sealing lip member is formed to be a peak.

6. The liquid treating apparatus according to claim 2, wherein the liquid sealing lip member is formed by an elastic member.

7. The liquid treating apparatus according to claim 1, wherein the second infiltration preventing member includes an upper lip component and a lower lip component which are disposed to be opposed to each other on both sides with a surface of the surface treated substance interposed therebetween.

8. The liquid treating apparatus according to claim 7, wherein tip portions of the upper lip component and the lower lip component are formed to be peaks, respectively.

9. The liquid treating apparatus according to claim 7 or 8, wherein at least one of the upper lip component and the lower lip component is formed by an elastic member.

10. The liquid treating apparatus according to claim 1, wherein an inner part of the treating solution contact prevention chamber is constituted to be maintained in a pressurizing state.

11. The liquid treating apparatus according to claim 1, wherein the treating solution contact prevention chamber is provided on an upstream side of a liquid treating start position A to be a liquid treating terminal position and is constituted to prevent a discharged solution from coming in contact with the surface treated substance in a position on an upstream side of the liquid treating start position A.

12. The liquid treating apparatus according to claim 11, wherein an end on an upstream side of a plate is inserted in an opening portion on an outlet side in the treating solution contact prevention chamber, which is positioned on a downstream side in a direction of delivery in the treating solution contact prevention chamber, and is positioned on an upstream side of the liquid treating chamber, and
there are disposed a first infiltration preventing member, between the end on the upstream side of the plate and the opening portion on the outlet side in the treating solution contact prevention chamber,
Which prevents the treating solution discharged from the treating solution discharging device and flowing to the upstream side along the surface treated substance, from infiltrating into the downstream side of the treating solution contact prevention chamber; and
a second infiltration preventing member for preventing the treating solution, which is discharged from the liquid discharging device and then floating in the chamber, from infiltrating into the downstream side of the treating solution contact prevention chamber; and
wherein the liquid treating apparatus includes a plate disposed below the treating solution discharging device and constituting a delivery surface of the surface treated substance.

13. The liquid treating apparatus according to claim 1, wherein the treating solution contact prevention chamber is provided on a downstream side of a liquid treating end position B to be a liquid treating terminal position and is constituted to prevent the discharged solution from coming in contact with the surface treated substance in a position on a downstream side of a liquid treating end position B.

14. The liquid treating apparatus according to claim 13, wherein an end on a downstream side of a plate is inserted in an opening portion on an inlet side in the treating solution contact prevention chamber, which is positioned on an upstream side in a direction of delivery in the treating solution contact prevention chamber, and positioned on a downstream side of the liquid treating chamber, and
there are disposed a first infiltration preventing member, between the end on the downstream side of the plate and the opening portion on the inlet side in the treating solution contact prevention chamber,
Which prevents the treating solution discharged from the treating solution discharging device and flowing to the downstream side along the surface treated substance, from infiltrating into the upstream side of the treating solution contact prevention chamber; and
a second infiltration preventing member for preventing the treating solution, which is discharged from the liquid discharging device and then floating in the chamber, from infiltrating into the uptream side of the treating solution contact prevention chamber.

15. The liquid treating apparatus according to claim 1, wherein the surface treated substance is a film carrier tape for mounting electronic component.

16. A liquid treating method for discharging a treating solution to a liquid treating surface of a substance to be surface treated by means of a treating solution discharging device for the surface treated substance which is supplied continuously, thereby carrying out a predetermined liquid treatment, comprising the steps of:
delivering the surface treated substance to pass through an inside of a treating solution contact prevention chamber, which is provided in an outer position in a direction of delivery of the surface treated substance from a liquid treating terminal position, in which a treating solution is discharged to the liquid treating surface of the surface treated substance by the treating solution discharging device; and
preventing the treating solution, which is discharged from the treating solution discharging device and flowing along the liquid treating surface of the surface treated substance, from infiltrating into the treating solution contact prevention chamber, by means of a first infiltration preventing member, which is disposed on the liquid treating terminal position side of the treating solution contact prevention chamber; and
preventing the treating solution, which is discharged from the treating solution discharging device and then floating in a chamber, from infiltrating into the treating solution contact prevention chamber, by means of a second infiltration preventing member disposed on an inside of the treating solution contact prevention chamber from the first infiltration preventing member; and
discharging the treating solution through the treating solution discharging device, thereby carrying out a predetermined liquid treatment for the surface treated substance, in the state that,
wherein the liquid treating apparatus serves to carry out a predetermined liquid treatment in a liquid treating chamber to be a limited space for the surface treated substance.
